(19) United States
(12) Patent Application Publication
(10) Pub. No.: US 2011/0110036 A1
(43) Pub. Date: May 12, 2011

(54) PASSIVE COOLING SYSTEM FOR PHOTO VOLTAIC MODULES

(76) Inventors: Mark Buchanan, Oslo (NO); Gaute Dominic Magnussen, Lysaker (NO); Lars Dysterud, Oslo (NO)

(21) Appl. No.: 12/922,076

(22) PCT Filed: Mar. 9, 2009
(86) PCT No.: PCT/NO2009/000082

§ 371 Date: Jan. 13, 2011

(30) Foreign Application Priority Data
Mar. 11, 2008 (NO) 2008 1283

(51) Int. Cl. H05K 7/20

(52) U.S. Cl. 361/690

(57) ABSTRACT

The present invention discloses a cooling fin assembly for Photo Voltaic Solar (PVS) panels providing an improved passive cooling of the PVS panels. Cooling fins as such do provide a good local cooling effect underneath the contacting surface of the fins. However, due to uneven air streams around the cooling fins, the temperature difference across a transversal direction relative to the direction of the fins may be high. This causes a severe degradation of the cooling systems effectiveness, and the resulting output form the PVS panel. According to the disclosure of this invention, an arrangement of transversal heat conducting materials provides a heat bridge providing a thermal relaxation time below a predefined threshold across the whole back side of the PVS panel, thereby improving the overall cooling effect of the PVS panel.

The present invention is related to Photo Voltaic Solar (PVS) panels, and especially to a passive cooling system improving the performance of the PV panels.

In order to comply with the world's growing energy needs, the use of solar energy is increasingly important. Over the last decade there has been an enormous increase in the use of photovoltaic cells. This has happened in accordance with the technological development and the accompanied price reduction of materials and other technology (for example inverters) which are used.

It is a problem that the output effect from photovoltaic cells is reduced when the temperature increases. On a hot summer day with direct sun exposure the cell temperature will quickly raise to more than 80° C. This problem increases of course with the use of photovoltaic cells in warmer climate, and applies for both photovoltaic cells based on focused light and for flat photovoltaic panels. Accordingly, there has been developed a large number of cooling devices for photovoltaic apparatuses, but none of them has gained commercial success for the use with ordinary photovoltaic panels. Photovoltaic cells based on focused light are almost completely dependent on having a cooling system in order to operate, and most of the development in cooling the devices has focused on the concentrator technology. Examples of cooling devices for photovoltaic apparatuses based on focused light can be found in U.S. Pat. No. 3,999,283, U.S. Pat. No. 5,498,297 and WO A1 96/15559.

WO A1 03/098705 disclose a photovoltaic module comprising a heat sink in thermal contact with the photovoltaic material. The heat sink of this publication comprises a plurality of fins 12 that are movable between a first position substantially parallel to the mounting surface of the heat sink and a second position non-parallel to the mounting surface of the heat sink. The first position of the fins is used when assembling a module for facilitating for example lamination of the heat sink to the photovoltaic material. However, even though the handling of the heat sink during production of the module is simplified, the actual manufacturing of the heat sink itself is complex. There are also additional problems related to locating and adjusting the fins of the heat sinks after installation of a panel according to this publication. Therefore, there is a need for a simplified design of a cooling system that is cost effective in manufacturing and assembly of photovoltaic modules.

Cooling can be provided by both active and passive systems. Active cooling systems include Rankine cycle system and absorption system, both of which require additional hardware and costs. Passive cooling systems make use of three natural processes: convection cooling, radiation cooling and evaporation cooling from water surfaces exposed to the atmosphere.

Often the temperature in the photovoltaic panels and modules are 30-50° C. higher than in the ambient air. This temperature increase results in 5-20% reduction of output effect from the photovoltaic panel. A disadvantage of many of the prior art cooling devices for photovoltaic panels and modules is that many of them are complicated and relatively costly to produce. Furthermore it has not been taken into consideration that a cooling device needs to be robust and maintenance free for the next 25-40 years which is the modules' life expectancy. None of the existing solutions has therefore awaked any great interest in the market of photovoltaic panels. Accordingly a need exists for a cooling system for photovoltaic panels and modules which is simple and inexpensive to produce and which is completely maintenance free.

One prior art approach to solve the cooling problem in a cost effective manner is to provide cooling fins attached to the backside of the PVS panel. See for example U.S. Pat. No. 4,118,249 A. The heat sink fin geometry acts to cool the module by convective air flow up the backside of the module. This cools the module rapidly up the back; however, heat transfer perpendicular to the air flow is relatively lower. This phenomenon has been documented for example by the Arizona State University (ASU). It is known from field test measurements from ASU that a module with heat sink arrangement can have a 25° C. temperature difference from the centre to the edge of the module. This reduces performance and lifetime of the module due to uneven current flow and stress gradients (due to variations in material expansion) across the module.

Such uneven temperature differences on the module surface impose a variety of problems in the module. There are a number of reasons why a homogeneous cooling rate is necessary across the surface of the solar panel:

Even current flow in the panel. Reducing excess load on the bypass diodes.

Reduced stress gradients in the module due to temperature changes. This results in a longer lifetime of the module.

Higher performance of the module. Higher power output.

Good heat transfer will also reduce the degradation in performance of “hot spots” that occur during shadowing.

Therefore, there is a need for an improved passive cooling module providing cost effective cooling with improved transversal cooling effect.

According to an example of embodiment of the present invention, a heat sink device comprising cooling fins, wherein the fins are oriented in an upwardly arrangement permitting airflow between the cooling fins from a bottom edge of the PVS panel to an upper edge of the PVS panel, is arranged, wherein the PVS panel is attached in thermal contact with a backside of the PVS panel, wherein the heat sink device comprises a least one heat bridge arranged in a transversal arrangement relative to the cooling fins orientation, wherein the heat bridge is providing a substantial homogenous temperature over the whole surface of the PVS panel within a relaxation time period below a predefined threshold level.

According to an aspect of the present invention, the threshold level for the thermal relaxation time is a function of the actual cooling module when it is actually in thermal contact with the PVS panel. According to an example of embodiment of the present invention, the relaxation time threshold is defined as the time elapsed when bringing a temperature of two distal points respectively located in each respective end of the heat bridge, wherein the temperature is measured on the PVS panel surface in these respective points under Standard Test Conditions (STC) as known to a person skilled in the art of Photo Voltaic Solar Panels. It is within the scope of the present invention to use other definitions of the relaxation time, providing other means for providing the effect of substantial equal temperatures across a surface of the PVS panel.

According to another example of embodiment of the present invention, the heat bridge is arranged as a base plate made of aluminium supporting the cooling fins, and wherein a thickness of the base plate is sufficient to provide a transversal heat conducting capacity of the base plate enabling the thermal relaxation time to be below the predefined threshold level.

According to another example of embodiment of the present invention, the heat bridge is arranged as a strip of thermal conducting material in thermal contact with an upper edge of the cooling fins, or at a bottom edge of the cooling fins, or at both the upper and lower edges, respectively, thereby providing the transversal arrangement of the heat bridge with a thermal relaxation time below the predefined threshold level.

According to another example of embodiment of the present invention, the heat bridge is arranged as strips or patches of heat conductive material arranged in between the heat sink device and the back side of the PVS panel when assembled, wherein the material of the strips or patches provides a heat conductive capacity providing the thermal relaxation time below the predefined threshold level.

According to another example of embodiment of the present invention, the heat bridge is arranged as a frame surrounding the PVS panel's outer perimeter, and wherein the frame comprises a heat conducting material providing the thermal relaxation time below the predefined threshold level.

According to another example of embodiment of the present invention, the heat bridge is arranged as a transversal part of a supporting external structure that is used when mounting the PVS panel at a location for utilization of the PVS panel.

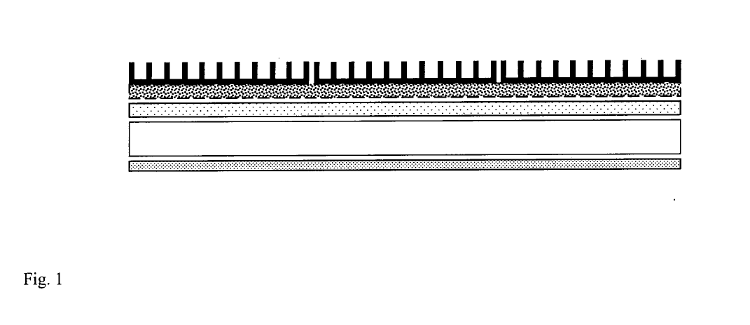

FIG. 1 illustrates a prior art PVS panel with passive cooling fins.

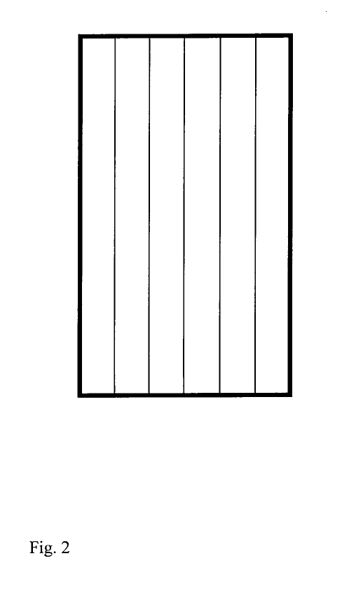

FIG. 2 illustrates a view of the cooling fins attached to the backside of the PVS panel in FIG. 1.

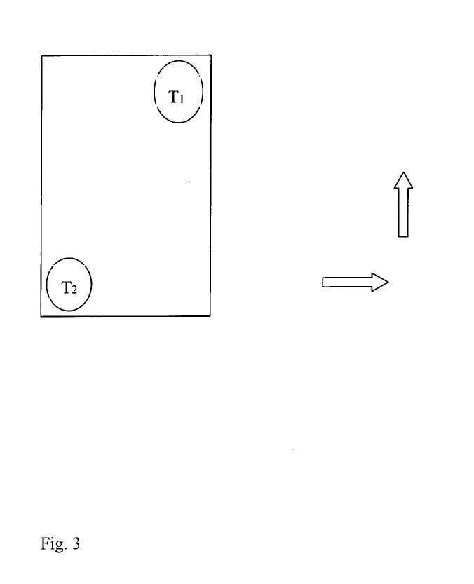

FIG. 3 illustrates the effect of uneven temperature between to separate location on the PVS panel.

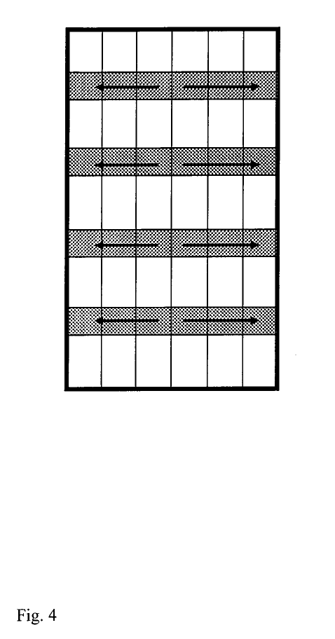

FIG. 4 illustrates an example of embodiment of the present invention.

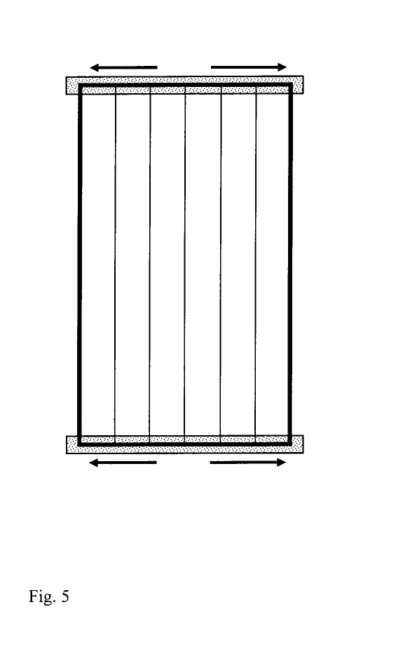

FIG. 5 illustrates another example of embodiment of the present invention.

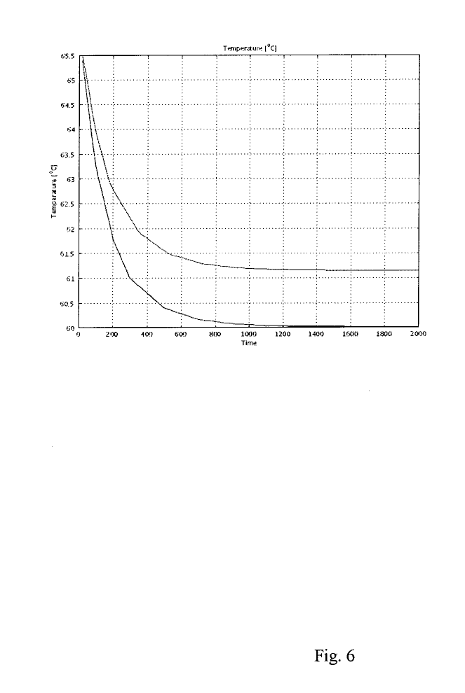

FIG. 6 illustrates the concept of thermal relaxation time.

FIG. 1 illustrates an example of a PVS panel being cooled by protruding cooling fins 10. The cooling fins can be manufactured as a collection of modules assembled onto the backside of the panel (as illustrated in FIG. 1) or as an unbroken module covering the whole backside of the PVS module. Thermal conducting glue 11 is used to connect the cooling fins 10 to the photo voltaic cells 13. However, in some examples of PVS modules, there can be an intermediate layer 12, for example made of tedlar. A cover 14 made of glass is the side of the PVS module that is facing the sun.

FIG. 2 illustrates the arrangement of the fins on a backside of a PVS panel. Air may flow from the bottom edge of the PVS module to the top edge of the module. However, the transversal cooling effect can be extremely variable. An effect of the arrangement of the cooling fins is that air flow in a transversal direction relative to the upwardly direction of the fins actually impair the air flow due to the protruding feature of the fins. According to field experiments conducted by research teams of Arizona State University, the temperature difference between a middle section of the PVS panel and sections close to the perimeter can be as much as 25° C. This seriously impair the performance of the PVS panel, and the effect of the cooling fins can actually contribute to harm the PVS panel in stead of promoting a long lifetime of the panel, for example. The uneven cooling provided by the cooling fins is also due to the fact that locally, just beneath a cooling fin section, the cooling can be extremely effective. This also contributes to the uneven temperature profile across the PVS panel. Such uneven temperatures affect the effectiveness of the photo voltaic cells directly, and the output from different cells is extremely different. Therefore, bypass diodes in the panel may be harmed, higher mechanical stress may be induced in structures, and lower power output than expected is the result. Therefore, an aspect of the present invention is to arrange a heat bridge in a transversal direction relative to the fin geometry that provides a thermal conductivity in this direction that substantially equalize the temperature difference between different locations on the PVS panel surface.

FIG. 3 illustrates a situation wherein two different spots T1 and T2 have different temperatures. The backside of this example of PVS panel has cooling fins (not shown) which provides an effective cooling from the bottom side of the panel to the upper edge of the panel. Therefore, any temperature difference along the underlying sections of a cooling fin is minimal when measuring the temperature at the bottom end of the cooling fin compared to the upper end of the cooling fin. It is the temperature difference that can be between the different local sections underneath the respective cooling fins, and the temperature difference that can be present between different sections of the PVS panel surface due to uneven air flow conditions, that causes the problem. Therefore, an additional heat transfer channel or bridge providing a good heat conducting capacity between the respective cooling fins in the transversal direction of the fin geometry is sufficient to substantially equalize the temperature between respective longitudinal sections of the cooling panel. This is illustrated in FIG. 3 such that heat flows from the T2 area first in a transversal direction due to an arranged heat bridge, and then along a longitudinal direction along a cooling fin to the area marked T1. It is important to understand that the location of the heat bridge between the two sections comprising respectively the T1 and T2 area do not necessarily have to be located close to any of the areas T1 and T2. Since the cooling fins provides a good longitudinal heat transfer capacity (due to air flow), any location of a heat bridge thermally connecting the respective cooling fins in a transversal direction is sufficient to achieve the goal of the present invention, as long as the cooling capacity of the heat bridge provides a reasonably quick substantial equalization of temperature between distal areas of the PVS panel.

FIG. 4 illustrates an example of embodiment of a cooling device according to the present invention comprising four transversal heat bridges. The arrows exemplify heat transfer form the middle section of the PVS panel to the outer sections of the PVS panel.

FIG. 5 illustrates another example of embodiment of the present invention wherein a heat bridge is arranged in a bottom part and an upper part of the PVS panel.

The heat bridge can also be embodied as a frame around the whole PVS panel, or be part of a supporting frame used when installing a PVS panel at location.

The heat bridge can be made of any material providing a transport of the heat according to the present invention, wherein the time elapsed for transporting heat should be low. Good heat conductors prove a quick relaxation time for the PVS panel providing an equal temperature profile across the panel almost instantaneously.

Examples of materials can be carbon paper, thermo conducting plastic materials, two phase materials, conductive adhesive materials etc. It is within the scope of the present invention to use any type of material, composition of materials, and/or any form of mechanical arrangement utilizing such materials providing the necessary relaxation time below a predefined threshold level. FIG. 6 illustrates the falling temperature as a function of elapsed time for an example of embodiment of the present invention. The crossing of the curve 60 on the time axis illustrates the threshold level of the relaxation time.

According to an example of embodiment of the present invention, the relaxation time threshold is defined as the time elapsed when bringing a temperature of two distal points respectively located in each respective end of the heat bridge, wherein the temperature is measured on the PVS panel surface in these respective points under Standard Test Conditions (STC) as known to a person skilled in the art of Photo Voltaic Solar Panels. According to another example of embodiment of the present invention, the predefined threshold level for the relaxation time is defined as elapsed time for transversal heat transfer per lateral meter of the actual cooling fin assembly used to cool the PVS panel when the cooling fin assembly is mounted on the backside of the panel, when operating under a STC environment.

Another effect of the heat bridge arrangement according to the present invention is to solve the problem of “hot spots” on a PVS panel surface. The PVS panels are usually located on the roof of a building, or other outdoor areas having clear view of the sky, wherein the panel surfaces are faced towards the sun. This insures exposure to the sun the whole day. However, other buildings, trees, etc. may provide a shadow on the surface of one or a multiple of panels. The shadow may also only cover a part of the surface. This provides the condition called “hot spot”. When some areas of the panel is in the shadow, and other parts are in the sun, the electrical and thermal conditions in the panel can decline to such an extent that the power output and lifetime of the panel may be permanently damaged. As can be understood by a person skilled in the art, a thermal bridge according to the present invention will substantially facilitate the problem with hot spots.

In an example of embodiment, in order to improve the performance of a solar panel with cooling system, thermal bridges are included in the solar panel. In this example of embodiment the thermal bridges reduces the thermal relaxation time in the solar panel. Thus the flow of heat across the solar panel is enhanced and a thermal relaxation time of about 5 mins has been observed.

In an example of a method for manufacturing a solar panel according to the present invention, which cools the panel substantially homogeneously, thermal bridges are included in the panel. The thermal bridges in the solar panel allow heat to be transported across transversely to the direction of the protruding cooling finns on the module such that a substantial homogeneous temperature difference across the surface is achieved.

Examples of method steps are:

1. The solar panel is constructed in a way known in prior art.

2. An adhesive is applied to module and/or cooling fins.

3. The cooling fins are then attached.

Applying a Bridging Material after Step Two:

The bridging can either be added, after step 2, where a high heat conducting material is applied that makes contact between each profile section. According to another aspect of the present invention the bridging could also be some heat conductive additives in the adhesive that allow the adhesive to act as a conductive heat source.

Applying Bridging Material after Stage Three:

After the cooling profiles are attached to the module thermal bridges can then be added to thermally connect the fins. A thermally conductive material, such as a paste, tape or metallic strip for example, can be attached between the cooling profiles, or be located in between the cooling fins and the underside of the cooling finns, and also be attached to the backside of the cooling fins and the surface of the module the cooling finns are attaced to. Examples of materials are listed in table 1 below. In other examples of embodiments, the bridge and bridge materials can be located along the entire strip, or at the edges, or at points between the cooling profiles.

The key requirements for the solar panel design in order to achieve a sufficient relaxation of heat in the solar panel is that the thermal bridge must be in thermal contact between the cooling fin plates. In an example of embodiment, such materials are
Sufficiently thermally conductive.
Cover a sufficient area where the profiles joins the module.
The conductivity of the bridge, k_{b} is at least 10^{-2.5}×kₐₗᵤ, where kₐₗᵤ, is the conductivity of aluminum.

According to an aspect of the present invention, in order to achieve sufficient heat transfer the area of bridge coverage (A_{b}/A_{T}) and thermal conductivity (K_{b}/Kₐₗ) should be sufficient to provide adequate thermal transfer. According to an example of embodiment of the present invention the following relationship between these parameters are:

(A_{b}/A_{T})×(K_{b}/K_{Al})>10^{-2.5}

For example, this can be satisfied using silver conductive paste between the cooling profiles. Further, applying a metal of equal conductivity or higher to abridge the cooling profiles at least 1% of the profile edge length. It is preferred that the location of the bridges should be as evenly spread as possible.

TABLE 1
Examples of materials with thermal conductivity properties
according to the present invention:

| | Thermal conductivity |
|---|---|
| Material | (W/(m · K) |
| Concrete | 1.7 |
| Thermal grease | 0.7-3 |
| Thermal Epoxy | 1-7 |
| Glass | 1.1 |
| Lead | 2.4 |
| Aluminium | 237 |
| Gold | 318 |
| Copper | 401 |
| Silver | 429 |
| Carbon | 900-2320 |
| Stainless steal | 11-45 |
| Carbon paper | 1000-2000 |

1. Photo Voltaic Solar (PVS) panel comprising:
a heat sink device comprising cooling fins oriented in an upwardly direction from a bottom edge of the panel to an upper edge of the panel permitting airflow between the cooling fins from the bottom edge of the PVS panel to the upper edge of the PVS panel, wherein the PVS panel is attached in thermal contact with a backside of the PVS panel, wherein the heat sink device comprises a least one heat bridge arranged in a transversal direction relative to the cooling fin direction, wherein the heat bridge provides a thermal relaxation time of the PVS panel below a predefined threshold level.

2. PVS panel according to claim 1, wherein the heat bridge is arranged as a base plate made of aluminium supporting the cooling fins, and wherein a thickness of the base plate enables the transversal heat conducting capacity of the base plate to be in accordance with the required relaxation time below the predefined threshold level.

3. PVS panel according to claim 1, wherein the heat bridge is arranged as a strip of thermal conducting material in thermal contact with an upper edge of the cooling fins, or at a bottom edge of the cooling fins, or at both the upper and lower edges, respectively, thereby providing the transversal arrangement of the heat bridge with a thermal relaxation time below the predefined threshold level.

4. PVS panel according to claim 1, wherein the heat bridge is arranged as strips or patches of heat conductive material arranged in between the heat sink device and the back side of the PVS panel when assembled, wherein the material of the strips or patches provides a heat conductive capacity providing the thermal relaxation time below the predefined threshold level.

5. PVS panel according to claim 4, wherein the strips or patches are made of carbon paper.

6. PVS panel according to claim 4, wherein the strips or patches are made of thermo-plastic folio.

7. PVS panel according to claim 4, wherein the strips or patches are made of thermo-conductive adhesive material.

8. PVS panel according to claim 1, wherein the heat bridge is arranged as a frame surrounding the PVS panel's outer perimeter, and wherein the frame comprises a heat conducting material providing the thermal relaxation time below the predefined threshold level.

9. PVS panel according to claim 1, wherein the heat bridge is arranged as a transversal part of a supporting external structure that is used when mounting the PVS panel at a location for utilization of the PVS panel.

10. PVS panel according to claim 1, wherein the predefined threshold level for the relaxation time is defined as elapsed time for transversal heat transfer per lateral meter of the actual cooling fin assembly used to cool the PVS panel when the cooling fin assembly is mounted on the backside of the panel, wherein the panel is operating under Standard Test Conditions.

11. PVS panel according to claim 1, wherein the relaxation time threshold is defined as the time elapsed when bringing a temperature of two distal points respectively located in each respective end of the heat bridge, wherein the temperature is measured on the PVS panel surface facing the sun under Standard Test Conditions.
